(19) United States
(12) Patent Application Publication
(10) Pub. No.: US 2026/0182317 A1
(43) Pub. Date: Jun. 25, 2026

(54) Method for Altering the Carrier Concentration of a Two-Dimensional Electron Gas

(71) Applicant: National Chung Shan Institute of Science and Technology, Taoyuan (TW)

(72) Inventors: Guan-Shian Liu, Taoyuan (TW); Vin-Cent Su, Taoyuan (TW); Chin-Tien Chen, Taoyuan (TW); Kuo-Jen Chang, Taoyuan (TW)

(21) Appl. No.: 18/988,685

(22) Filed: Dec. 19, 2024

(51) Int. Cl. H01L 21/322; H01L 21/02

(52) U.S. Cl. CPC H10P 95/408; H10P 14/2904; H10P 14/2905; H10P 14/2921

(57) ABSTRACT

A method for altering the carrier concentration of a two-dimensional electron gas (2DEG) in an epitaxial layer structure is provided. This method involves forming various micro- and nano-scale structures on a substrate. Under a later specific epitaxial growth conditions, these structures induce varying degrees of stress accumulation or relaxation in the epitaxial layer structure. Such stress accumulation or relaxation indirectly modifies the energy band distribution at the heteroepitaxial interface within the epitaxial layer structure, thereby affecting the carrier concentration of the two-dimensional electron gas.

### BACKGROUND

### Technical Field

The present invention relates to a method for altering the carrier concentration of a two-dimensional electron gas in an epitaxial layer structure, particularly to a method for modulating the carrier concentration of a two-dimensional electron gas at a heterojunction by forming various micro- and nano-scale structures on a silicon carbide substrate.

### Description of Related Art

The third-generation semiconductors can be classified into two major systems: gallium nitride (GaN) and silicon carbide (SiC). The silicon carbide system is commonly used in high-power devices due to the inherent advantages of its wide bandgap and high thermal conductivity. In contrast, the gallium nitride system, which generates a two-dimensional electron gas (2DEG) at the heteroepitaxial interface, has been developed for applications in radio frequency (RF) devices. Recently, to develop high-power RF devices, the composite system—gallium nitride epitaxially grown on a silicon carbide substrate—has emerged. However, this composite system still employs traditional heteroepitaxial methods to generate high-density two-dimensional electron gas.

In addition, the gallium nitride material system paired with sapphire substrates has become the preferred choice for producing blue light-emitting diodes (LEDs). The brightness enhancement of blue LEDs can be achieved by improving both the internal quantum efficiency and the light extraction efficiency of the diode. The current mass production method employs patterned sapphire substrate (PSS) technology, which not only reduces the defect density in the epitaxial layer, thereby enhancing the internal quantum efficiency of the diode, but also utilizes patterned structures to improve light extraction efficiency. However, this method of reducing the defect density in the epitaxial layer works by suppressing defects at the bottom of the epitaxial layer (within the GaN buffer layer), thereby reducing the propagation of threading dislocations (TDs) to the surface. This approach does not significantly alter the internal stress of the overall epitaxial layer.

The aforementioned composite system generates a two-dimensional electron gas (2DEG) using heteroepitaxial methods, which face the limitation that, under specific epitaxial conditions, a single epitaxial wafer can only produce a specific carrier concentration of the two-dimensional electron gas. Furthermore, this heteroepitaxial method often encounters issues with the uniformity of the epitaxial layer on a single wafer, making it impossible to achieve a uniform distribution of the 2DEG concentration across the entire wafer. This lack of uniformity significantly impacts the yield of subsequent devices.

Additionally, conventional patterning techniques are typically used to enhance the brightness of light-emitting diodes and cannot significantly modulate or locally alter the internal stress within the epitaxial layer. Furthermore, there is no prior literature suggesting that patterning substrate techniques can be employed to modulate the two-dimensional electron gas in heteroepitaxial methods.

Furthermore, from fundamental materials science, it is known that common dislocation defects in the epitaxial layer can be categorized into edge dislocations, screw dislocations, and mixed dislocations. The generation or reduction of these dislocation defects corresponds to the accumulation or release of stress. By modulating the number of dislocation defects in the epitaxial layer, it is possible to indirectly affect the concentration of the two-dimensional electron gas.

In summary, there are still defects in modulating the carrier concentration of a two-dimensional electron gas in heteroepitaxial methods. Therefore, the applicant has conducted extensive research and developed a method for altering the carrier concentration of a two-dimensional electron gas, which can modulate the number of dislocation defects within the epitaxial layer, thereby indirectly influencing the carrier concentration of the two-dimensional electron gas.

### SUMMARY

In view of the drawbacks of the prior art, the main aspect of the present invention is to employ a patterned structure on a silicon carbide substrate, using micro- and nano-structures fabricated on the substrate. Under specific epitaxial growth conditions, this approach generates varying defect densities within the epitaxial layer, corresponding to different stress accumulation or release within the layer. Such accumulated or released stress can indirectly alter the energy band distribution at the heteroepitaxial interface, thereby affecting the carrier concentration of the two-dimensional electron gas.

Accordingly, a method for altering a carrier concentration of a two-dimensional electron gas in an epitaxial layer structure is provided. The method comprises the following steps. A silicon dioxide layer is grown on an epitaxial substrate. The silicon dioxide layer is patterned to form a plurality of silicon dioxide pillars on the epitaxial substrate. An aluminum nitride layer is epitaxially grown on the plurality of silicon dioxide pillars and the epitaxial substrate. A gallium nitride layer is epitaxially grown on the aluminum nitride layer to form an epitaxial layer structure, which sequentially comprises the substrate, the silicon dioxide pillars, the aluminum nitride layer, and the gallium nitride layer from bottom to top. The plurality of silicon dioxide pillars generate varying defect densities within the epitaxial layer structure, thereby modifying the internal stress within the epitaxial layer structure, indirectly altering the energy band distribution at the heteroepitaxial interface, and consequently changing the carrier concentration of the two-dimensional electron gas.

According to an embodiment of this invention, the plurality of silicon dioxide pillars are hexagonal pillars, each having a hexagonal top surface, and the distance between one vertex of the hexagon and the corresponding vertex of an adjacent hexagon defines a period.

According to another embodiment of this invention, the diameter of the hexagon is determined based on the ratio of the area of the hexagon to the area of a square, the side length of the square being equal to the period.

According to yet another embodiment of this invention, the ratio of the area of the hexagon to the area of the square is between 1% and 40%.

According to yet another embodiment of this invention, the ratio of the area of the hexagon to the area of the square is 20%.

According to yet another embodiment of this invention, the formula for determining the diameter of the hexagon is as follows:

$${P}^{2} \times A ( \% ) = \frac{3 \sqrt{3}}{2} \times {S}^{2}$$

where P represents the period, A (%) denotes the ratio of the area of the hexagon to the area of the square expressed as a percentage, and S is half of the diameter of the hexagon.

According to yet another embodiment of this invention, the epitaxial substrate is silicon carbide, sapphire, or silicon.

The above summary, along with the detailed description and accompanying drawings, is provided to further illustrate the methods, means, and effects employed by the present invention to achieve its intended objectives. Other purposes and advantages of the invention will be further explained in the subsequent description and figures.

### BRIEF DESCRIPTION OF THE DRAWINGS

FIG. 1 is a schematic diagram of the epitaxial layer structure according to an embodiment of the present invention.

FIG. 2 is a schematic diagram of the patterned silicon dioxide layer according to an embodiment of the present invention.

FIG. 3 is a schematic diagram of the silicon dioxide pillars according to an embodiment of the present invention.

### DETAILED DESCRIPTION

The following describes specific embodiments of the present invention, which can be easily understood by those skilled in the art based on the content disclosed in this specification, allowing them to appreciate the advantages and effects of the invention.

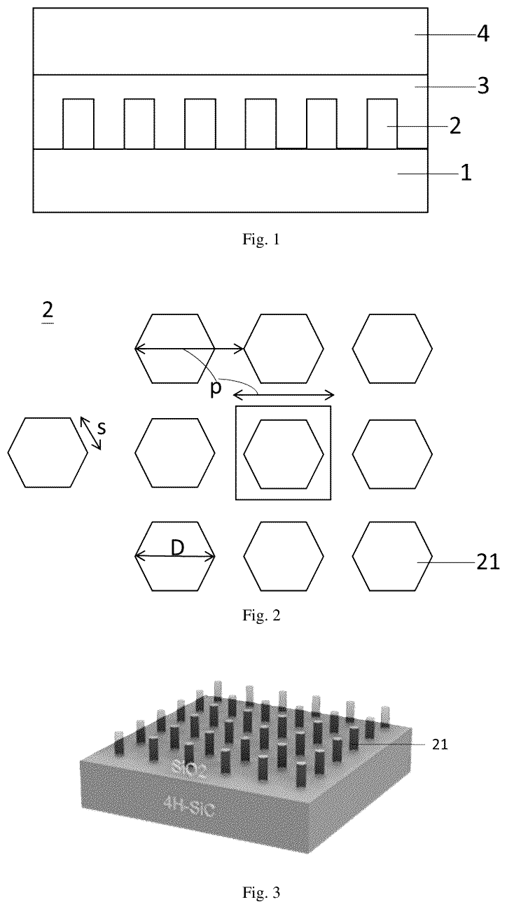

Referring to FIGS. 1 and 2, FIG. 1 is a schematic diagram of the epitaxial layer structure according to an embodiment of the present invention, and FIG. 2 is a schematic diagram of the patterned silicon dioxide layer according to an embodiment of the present invention. A method for altering the carrier concentration of a two-dimensional electron gas in an epitaxial layer structure comprises the following steps: First, a silicon dioxide layer 2 is grown on an epitaxial substrate 1. The epitaxial substrate may be silicon carbide, sapphire, or silicon.

Next, the silicon dioxide layer 2 is patterned to form a plurality of silicon dioxide pillars 21 on the epitaxial substrate 1. In this embodiment, the process for patterning the silicon dioxide layer 2 may include the following steps: depositing silicon dioxide by Plasma-Enhanced Chemical Vapor Deposition (PECVD), depositing a conductive layer using an E-Gun Evaporation system, performing E-Beam exposure using Electron Beam Lithography (EBL), depositing a nickel (Ni) hard mask using an E-Gun Evaporation system, etching the silicon dioxide layer using Reactive Ion Etching (RIE), and etching the silicon carbide using Inductively Coupled Plasma Reactive Ion Etching (ICP-RIE), resulting in the formation of a plurality of silicon dioxide pillars 21, as shown in FIG. 3.

Then, an aluminum nitride layer 3 is epitaxially grown on the plurality of silicon dioxide pillars 21 and the epitaxial substrate 1. A gallium nitride layer 4 is epitaxially grown on the aluminum nitride layer 3 to form an epitaxial layer structure, which sequentially comprises the substrate 1, the silicon dioxide pillars 21, the aluminum nitride layer 3, and the gallium nitride layer 4 from bottom to top. In this embodiment, the epitaxial growth process may be performed using either Metal-Organic Chemical Vapor Deposition (MOCVD) or Molecular Beam Epitaxy (MBE). In this example, a 4-inch intrinsic 4H—SiC substrate is used, and epitaxial growth is carried out via MOCVD. The structure, from bottom to top, sequentially comprises: a Si-face 4H—SiC silicon carbide substrate 1, a 500 nm silicon dioxide pillars 21, a 50 nm aluminum nitride layer 3, and a 1.8 μm gallium nitride layer 4.

Through the aforementioned steps, a plurality of silicon dioxide pillars 21 generate varying defect densities within the epitaxial layer structure, thereby modifying the internal stress of the epitaxial layer. This, in turn, indirectly alters the energy band distribution at the heteroepitaxial interface, resulting in a change in the carrier concentration of the two-dimensional electron gas.

Referring to FIG. 2, in this embodiment, the plurality of silicon dioxide pillars 21 may be hexagonal prisms. Each hexagonal prism has a hexagonal top surface (the hexagon is viewed from the top, showing the shape of the hexagon), and the distance from one vertex of the hexagon to the corresponding vertex of next hexagon represents the period P length. The diameter D of the hexagon is determined by the ratio of the hexagonal area to the area of a square box, where the side length of the square box is the period P length, which corresponds to the distance between the vertices of adjacent hexagons.

The formula for determining the diameter D of the hexagon is as follows:

$${P}^{2} \times A ( \% ) = \frac{3 \sqrt{3}}{2} \times {S}^{2}$$

where P represents the period, A (%) denotes the ratio of the area of the hexagon to the area of the square expressed as a percentage, and S is half of the diameter of the hexagon (i.e., the length of the side of the hexagon).

For example, with a period P=1100 nm, when the goal is to determine the diameter D of the hexagon that occupies 10% of the square box area, the values can be substituted into the formula to obtain

$${1100}^{2} \times 10 ( \% ) = \frac{3 \sqrt{3}}{2} \times {S}^{2} .$$

By rearranging the equation, the value of S can be calculated, and then multiplied by 2 to obtain the diameter D of the hexagon (i.e., 2S). Table 1 summarizes the diameters D of hexagons with period P=1100 nm and A (%) of 1%, 5%, 10%, 15%, 20%, 30%, and 40%. The table shows the calculated diameters D for these area ratios in the silicon dioxide pillars 21. Additionally, the pattern area size is 200 μm×200 μm.

TABLE 1
The diameter of the hexagon when
P is 1100 nm and A(%) is 1%-40%.

| Period (nm) | Area Ratio | 1100 |
|---|---|---|
| Diameter (nm) | 1% | 136 |
| | 5% | 305 |
| | 10% | 432 |
| | 15% | 529 |
| | 20% | 610 |
| | 30% | 748 |
| | 40% | 863 |

Table 2 summarizes the measurement results of edge dislocation densities for a period P=1100 nm with area ratios of 1%, 5%, 10%, 15%, 20%, 30%, 40%, and the blank region. From the table, it can be observed that as the area ratio increases (from 1% to 20%), the edge dislocation density decreases correspondingly (reaching its lowest at 20%). However, when the area ratio exceeds 20%, the edge dislocation density starts to increase again. This is attributed to the fact that at area ratios of 30% and 40%, the diameter D becomes too large, reducing the areas between patterns that can release dislocations. Conversely, at an area ratio of 1%, the diameter D is too small, making the pattern resemble a blank region, which explains why the measured value is similar to that of the blank region.

TABLE 2
Cathodoluminescence (CL) Measurement Results

| Area Ratio A(%) | edge dislocation densities (cm⁻²) |
|---|---|
| 1% | 4.20 × 10⁸ |
| 5% | 3.92 × 10⁸ |
| 10% | 3.92 × 10⁸ |
| 15% | 3.88 × 10⁸ |
| 20% | 3.64 × 10⁸ |
| 30% | 3.92 × 10⁸ |
| 40% | 4.44 × 10⁸ |
| Blank area | 4.04 × 10⁸ |

In summary, the method of altering the carrier concentration of a two-dimensional electron gas in an epitaxial layer structure as described in this invention achieves the capability of producing epitaxial wafers with varying two-dimensional electron gas concentrations on a single epitaxial substrate, even under identical epitaxial growth conditions, by using heteroepitaxy on differently patterned silicon oxide layer on silicon carbide substrates. This approach provides the benefits and advantages of achieving diverse two-dimensional electron gas concentrations on a single wafer.

Additionally, this invention enables the production of patterned silicon carbide templates with gallium nitride buffer layers, offering significant commercial value. The technique of patterning silicon carbide substrates, as it is compatible with photolithography or nanoimprint processes, facilitates the mass production of patterned silicon carbide substrates, further enhancing its commercial potential.

The aforementioned embodiments are provided solely to illustratively describe the characteristics and advantages of the present invention and are not intended to limit the scope of its substantive technical content. Any modifications or variations to the described embodiments made by those skilled in the art, without departing from the spirit and scope of the invention, shall fall within the protection scope of the invention as defined by the claims set forth below.

What is claimed is:

1. A method for altering a carrier concentration of a two-dimensional electron gas in an epitaxial layer structure, comprising the steps of:
growing a silicon dioxide layer on an epitaxial substrate;
patterning the silicon dioxide layer to form a plurality of silicon dioxide pillars on the epitaxial substrate;
epitaxially growing an aluminum nitride layer on the plurality of silicon dioxide pillars and the epitaxial substrate;
epitaxially growing a gallium nitride layer on the aluminum nitride layer to form the epitaxial layer structure from bottom to top sequentially comprising the substrate, the silicon dioxide pillars, the aluminum nitride layer, and the gallium nitride layer,
wherein the plurality of silicon dioxide pillars generate varying defect densities within the epitaxial layer structure, thereby modifying the internal stress within the epitaxial layer structure, indirectly altering the energy band distribution at the heteroepitaxial interface, and consequently changing the carrier concentration of the two-dimensional electron gas.

2. The method of claim 1, wherein the plurality of silicon dioxide pillars are hexagonal pillars, each having a hexagonal top surface, and the distance between one vertex of the hexagon and the corresponding vertex of an adjacent hexagon defines a period.

3. The method of claim 2, wherein the diameter of the hexagon is determined based on the ratio of the area of the hexagon to the area of a square, the side length of the square being equal to the period.

4. The method of claim 3, wherein the ratio of the area of the hexagon to the area of the square is between 1% and 40%.

5. The method of claim 3, wherein the ratio of the area of the hexagon to the area of the square is 20%.

6. The method of claim 3, wherein the formula for determining the diameter of the hexagon is as follows:
$${P}^{2} \times A ( \% ) = \frac{3 \sqrt{3}}{2} \times {S}^{2}$$
where P represents the period, A (%) denotes the ratio of the area of the hexagon to the area of the square expressed as a percentage, and S is half of the diameter of the hexagon.

7. The method of claim 1, wherein the substrate is silicon carbide, sapphire, or silicon.
